(19) United States
(12) Patent Application Publication
(10) Pub. No.: US 2008/0011351 A1
(43) Pub. Date: Jan. 17, 2008

(54) Dye-sensitized solar cell and method for manufacturing the same

(76) Inventors: Eric Wei-guang Diau, Hsinchu (TW); Chien-chon Chen, Hsinchu (TW)

Correspondence Address: MARTINE PENILLA & GENCARELLA, LLP, 710 LAKEWAY DRIVE, SUITE 200, SUNNYVALE, CA, 94085, US

(21) Appl. No.: 11/707,432

(22) Filed: Feb. 15, 2007

(30) Foreign Application Priority Data
Jul. 11, 2006 (TW) 95125195

(51) Int. Cl. H01L 31/0216

(52) U.S. Cl. 136/256

(57) ABSTRACT

A dye-sensitized solar cell comprises a metal substrate, a photosensitive dye, a transparent substrate, an insulating unit and an electrolytic solution. The metal substrate is made of titanium or titanium alloy and is used as an anode. A titanium dioxide (TiO₂) thin film is provided on the surface of the metal substrate, and consists of a plurality of arranged TiO₂ nanotubes. The photosensitive dye is absorbed on the surface of the metal substrate. A cathode is provided on a surface of the transparent substrate whose transparent part is a euphotic zone through which light can be irradiated to the photosensitive dye. The insulating unit is located between the anode and the cathode. The electrolytic solution fills the space between the anode and the cathode and surrounded by the insulating unit. A method for manufacturing the same is also disclosed.

### BACKGROUND OF THE INVENTION

a) Field of the Invention

The invention relates to a dye-sensitized solar cell and a method for manufacturing the same, particularly, the invention relates to a dye-sensitized solar cell comprising a TiO₂ nanotube array and a method for manufacturing the same.

b) Description of the Related Art

Presently there are several technical schemes of solar cells including monocrystalline/polycrystalline silicon solar cells, amorphous silicon solar cells, thin film solar cells and wet type dye-sensitized solar cells, among which the monocrystalline silicon solar cell takes the leading position in the market for its higher transformation efficiency (12%˜20%). However, since the monocrystalline silicon wafers of monocrystalline silicon solar cells are expensive, the manufacturing costs of solar cells are high.

A dye-sensitized solar cell is gradually becoming popular and being developed for its lower costs and simple manufacturing process. A dye-sensitized solar cell comprises an anode, an electrolytic solution and a cathode, wherein a semiconductor layer is formed on the surface of the anode and photosensitive dyes are absorbed therein. The reaction steps of the dye-sensitized solar cell are as follows:
1. After being irradiated by incident lights, the electrons of the photosensitive dye are excited from ground state to excited state;
2. The electrons transfer from excited state of the photosensitive dye molecules to a conductive band of the semiconductor layer, the electrolytic solution is oxidized simultaneously and the photosensitive dye is reduced. This process corresponds to holes transferring from photosensitive dye molecules to an electrolytic solution;
3. The electrons in the semiconductor layer then transfer from a conductive layer to an external circuit and do work on external loads;
4. The electrons return to the electrolytic solution from the external circuit via the cathode and reduce the electrolytic solution.

Most of conventional dye-sensitized solar cells utilize TiO₂ grains as a semiconductor layer. To manufacture a conventional dye-sensitized solar cell, TiO₂ grains are prepared first and then the prepared grains are coated or deposited on a substrate. However, there are still many defects to be improved. For example, the preparation method for TiO₂ grains is complicated, and it takes too much time or needs several chemicals and organic solutions to complete; also the uniformity of the produced TiO₂ grains is not good enough, in turn affects the evenness of the succeeding thin film to be coated. Moreover, the photosensitive dye, as illustrated in FIG. 1, utilizes the clearances between TiO₂ grains 11 as absorption areas. With the curved paths between the grains 11, the transmission rate of the electrons is not good because of the longer route for the electrons to be transferred to an external circuit via the conductive layer 12. In addition, the irregular paths between TiO₂ grains also complicate theoretical analysis of electron transmission.

In short, how to simplify the process of manufacturing dye-sensitized solar cells and improve the structure of the semiconductor layer at the same time to increase the transmission rate of electrons are the goals to be strived for.

### BRIEF DESCRIPTION OF THE INVENTION

In view of the abovementioned problems, an object of the invention is to provide a dye-sensitized solar cell and a method for manufacturing the same. Such dye-sensitized solar cell comprises a TiO₂ nanotube array as the semiconductor layer, which requires a simple manufacturing process and short manufacturing time, and provides a high uniformity of the produced semiconductor layer as well as improves the structure of the semiconductor layer to increase the transmission rate of electrons.

In order to achieve the above object, the dye-sensitized solar cell of the invention comprises a metal plate, a photosensitive dye, a transparent substrate, an insulating unit and an electrolytic solution. The metal plate is made of titanium or titanium alloy as an anode. A TiO₂ thin film is provided on the surface of the metal plate, which is formed by a plurality of arranged TiO₂ nanotubes. The photosensitive dye is absorbed on the surface of the metal plate. A cathode is formed on the surface of the transparent substrate whose transparent part is a euphotic zone through which light can be irradiated to the photosensitive dye. The insulating unit is disposed between the anode and the cathode. The electrolytic solution fills the space between the anode and the cathode and surrounded by the insulating unit.

The method for manufacturing a dye-sensitized solar cell in accordance with the invention includes the steps of:
1. forming a TiO₂ thin film on a surface of a metal plate made of titanium or titanium alloy, wherein such TiO₂ thin film consists of a plurality of arranged TiO₂ nanotubes, and the metal plate is used as an anode;
2. performing a thermal operation to change the TiO₂ nanotubes from a crystal structure of amorphous phase into a crystal structure of anatase phase;
3. absorbing a photosensitive dye onto the surface of the metal plate;
4. forming a cathode on the surface of a transparent substrate whose transparent part is a euphotic zone through which light can be irradiated to the photosensitive dye; and
5. filling the space between the anode and the cathode and surrounded by an insulating unit with an electrolytic solution to form the dye-sensitized solar cell.

According to the invention, the TiO₂ thin film is a structure of nanotubes, which can shorten the path for the electrons to travel from the photosensitive dye to the conductive layer. And the method for manufacturing a dye-sensitized solar cell in accordance with the invention utilizes an anode treatment method to directly grows a TiO₂ thin film layer on a metal plate, which provides the advantages of simple manufacturing process, short manufacturing time, excellent adhesion between the TiO₂ thin film and the metal plate and growing TiO₂ thin films on both sides of the metal plate simultaneously. In addition, the regular arrangement and the uniform diameter of the nanotubes facilitate the transmission rate of the electrons in the TiO₂ thin film layer.

### BRIEF DESCRIPTION OF THE DRAWINGS

FIG. 1 is a schematic drawing of a structure of TiO₂ thin film in a conventional dye-sensitized solar cell;

FIG. 2 is a schematic drawing of a dye-sensitized solar cell in accordance with a preferred embodiment of the present invention;

FIG. 3A is a schematic drawing of a cathode structure in a dye-sensitized solar cell in accordance with a preferred embodiment of the present invention;

FIG. 3B is a schematic drawing of another cathode structure in a dye-sensitized solar cell in accordance with a preferred embodiment of the present invention;

FIG. 4A is a photomicrograph of a produced TiO₂ thin film after performing anode treatment on a metal plate for 0.2 hour;

FIG. 4B is a photomicrograph of a produced TiO₂ thin film after performing anode treatment on a metal plate for 10 hours;

FIG. 5 is a diagram of a photoelectric current showing the current density when a preferred embodiment of the present invention is being illuminated;

FIG. 6 is a schematic drawing of a structure of a TiO₂ thin film in a dye-sensitized solar cell in accordance with the present invention.

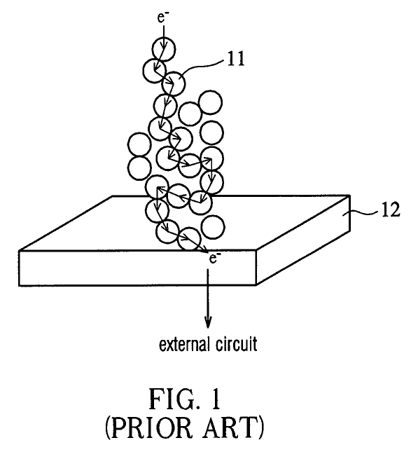

### DETAILED DESCRIPTION OF SPECIFIC EMBODIMENTS

The preferred embodiments of the invention will be explained below referring to the related drawings. Like components are denoted by like reference numerals.

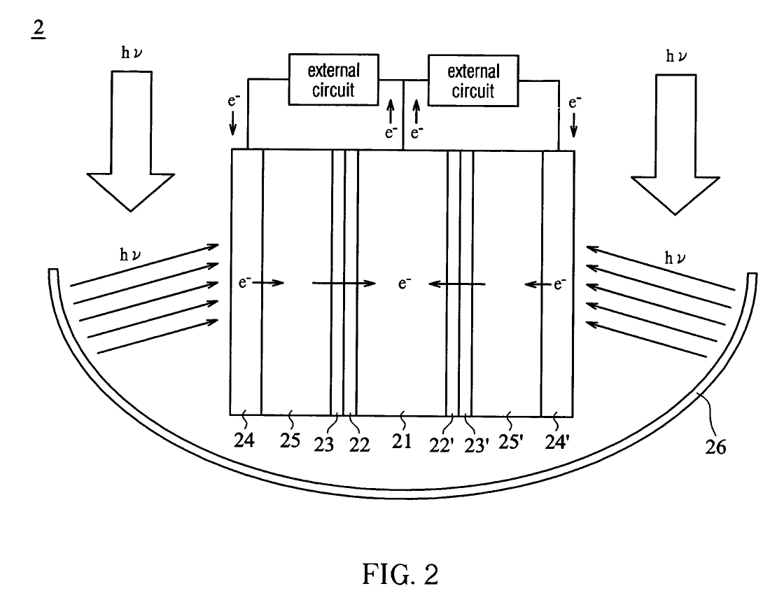

As illustrated with respect to FIG. 2, a dye-sensitized solar cell 2 in accordance with a preferred embodiment of the invention comprises a metal plate 21, a photosensitive dye 23, a transparent substrate 24, an insulating unit (not shown) and an electrolytic solution 25.

The metal plate 21 is made of titanium or titanium alloy, such as Ti-6A1-4V. A TiO₂ thin film 22 is provided on a surface of the metal plate 21 that is used as an anode of the dye-sensitized solar cell 2. The TiO₂ thin film 22 consists of a plurality of arranged TiO₂ nanotubes. The thickness of the metal plate 21 is 0.01˜2 mm, the thickness of the TiO₂ thin film 22 is 0.3˜20 μg™ m and the diameter of the TiO₂ nanotubes is 20˜100 nm. Since the metal plate 21 has a larger elastic deformation area, it can be made into a flexible electrode.

The absorption wavelength of the photosensitive dye 23 ranges from 400 to 1000 nm, wherein the photosensitive dye 23 can be a dye of one kind only or dyes of many kinds mixed together to absorb lights with specific wavelengths. The photosensitive dye 23 is absorbed on the surface of the metal plate 21, i.e. in the clearances of the TiO₂ nanotubes, e.g. the hollow part in the TiO₂ nanotubes or the gaps between the TiO₂ nanotubes. The photosensitive dye 23 is absorbed primarily in the hollow part in the TiO₂ nanotubes.

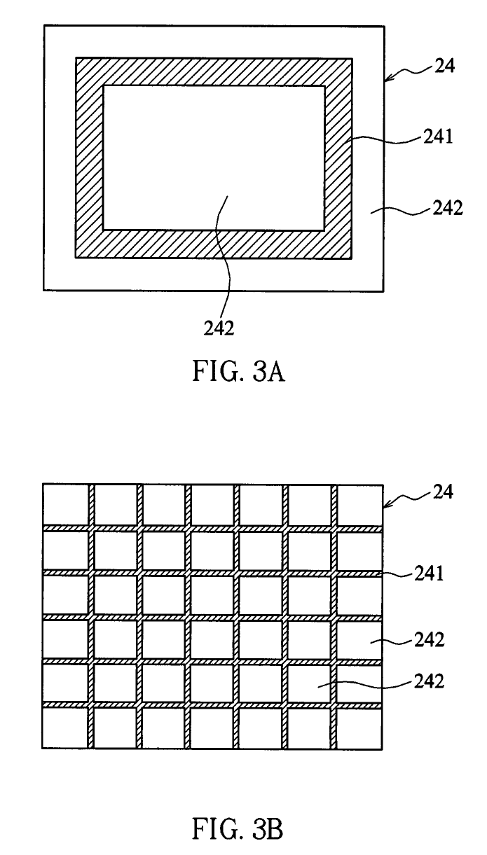

A cathode 241 is provided on a surface of the transparent substrate 24. For example, an electrode made of platinum, graphite or carbon nanotube can be formed on the surface of the transparent substrate 24 by deposition method. As illustrated in FIG. 3, the cathode 241 made of the above materials opacifies the cathode area of the transparent substrate 24. The rest transparent area of the transparent substrate 24 is called euphotic zone 242 through which light can be irradiated to the photosensitive dye 23. It is to be noted that the cathode 241 can also be made into the network structure as illustrated in FIG. 3B so that light can be irradiated to the photosensitive dye 23 through the meshed euphotic zone 242.

An insulating unit is disposed between the anode and the cathode, i.e. between the metal plate 21 and the transparent substrate 24, to isolate the anode and the cathode such that short circuit doesn't occur. Moreover, the space between the metal plate 21 and the transparent substrate 24 and surrounded by the insulating unit is filled with an electrolytic solution 25. The insulating unit is made of non-conductive materials, such as silica gel, plastic, rubber, polymer film or non-conductive ceramics. The electrolytic solution 25 can be a solution or a colloidal solution containing iodine ions. The iodine ions in the electrolytic solution 25 can perform the following oxidation and reduction reactions to release or absorb electrons.

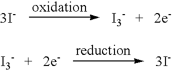

The dye-sensitized solar cell 2 in accordance with the preferred embodiment further comprises a reflection unit 26 for reflecting light to the euphotic zone 242. The reflection unit 26 can be a metal plate, a piece of glass or plastic that can reflect light.

The method for manufacturing a dye-sensitized solar cell 2 in accordance with a preferred embodiment of the invention is explained below. First, a TiO₂ thin film 22 is formed on a surface of a metal plate 21 made of titanium or titanium alloy, such TiO₂ thin film 22 consists of a plurality of arranged TiO₂ nanotubes, and the metal plate 21 is used as an anode of the dye-sensitized solar cell 2. Then a thermal operation is performed to change the TiO₂ nanotubes from a crystal structure of amorphous phase into a crystal structure of anatase phase having photocatalysis effect. Further, a photosensitive dye 23 is absorbed onto the surface of the metal plate 21, i.e. in the clearances of the TiO₂ nanotubes. Moreover, a cathode 241 is formed on a surface of a transparent substrate 24. Next, the space between the metal plate 21 and the transparent substrate 24 and surrounded by an insulating unit is filled with an electrolytic solution 25 to form the dye-sensitized solar cell 2. The temperature for the thermal operation should be kept within the range between 250° C. and 500° C. for 0.5˜5 hours.

The method for manufacturing a dye-sensitized solar cell 2 in accordance with the preferred embodiment of the invention further comprise providing a reflection unit for reflecting light to the euphotic zone of the transparent substrate 24.

The method of preparing a TiO₂ thin film 22 on the surface of the metal plate 21 is explained in detail below. A titanium metal plate of 99.7% purity is used as an example. The titanium metal plate is put in an air furnace with a temperature under 850° C. for annealing for one hour, then it is rinsed with 0.13% hydrofluoric acid (HF) to remove the TiO₂ thin film formed after annealing so as to ensure the microstructure of a phase of the titanium metal plate and eliminate the remaining stress inside the titanium metal plate. Next, the titanium metal plate is processed by electrochemical anode treatment to generate TiO₂ nanotubes on the surface of the titanium metal plate and regularly arranged array of TiO₂ nanotubes becomes a TiO₂ thin film 22. It is to be noted that the process of annealing and rinsing with hydrofluoric acid (HF) can be skipped.

0.5˜5% fluoride is the primary element for the electrolytic solution in anode treatment, such as hydrofluoric acid (HF), sodium fluoride (NaF), potassium fluoride (KF), ammonium fluoride (NH₄F), or a combination thereof. The secondary element for the electrolytic solution in anode treatment is 5˜30% compound free of halogen element, such as the following compounds: ((NH₄)H₂PO₄), ((NH₄)SO₄), (H₂C₂O₄) etc., or acid solutions like (H₂SO₄), (H₃PO₄) or (HNO₃). The temperature for the electrolytic solution in anode treatment is within the range of 1° C. to 30° C. The voltage for anode treatment is within the range of DC 12V to 40V. The process time for anode treatment is within the range of 0.5 hr to 24 hrs.

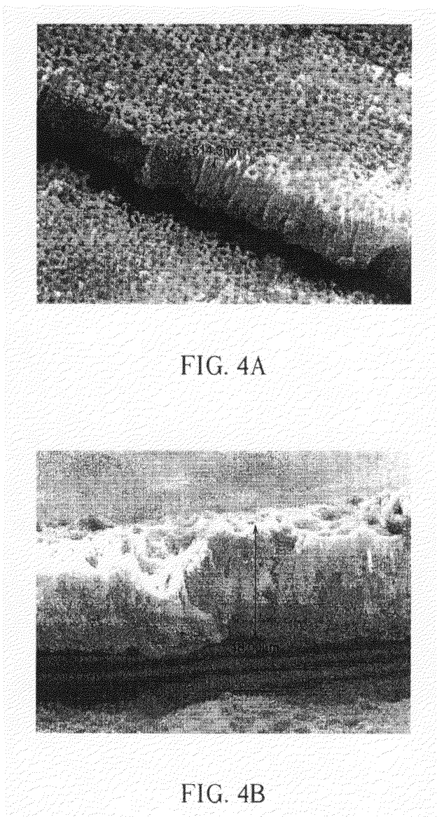

For example, an electrolytic solution composed of 0.1M KF, 1M NaHSO₄ and 0.2M (C₆H₅O₇Na₃.H₂O) with pH value maintained at 5 and temperature maintained at room temperature is prepared for anode treatment. When a DC voltage of 18˜25V is imposed thereon, the thickness of the TiO₂ thin film grows gradually from 0.5 μm to 18 μm as the process time for anode treatment increases from 0.2 hr to 10 hrs, as shown in FIGS. 4A and 4B. The diameter of voids in the TiO₂ thin film is around 100 nm. The thickness of the void wall is around 20 nm while the void density is around 10¹⁰/cm². Then the titanium metal plate after anode treatment is put in an air furnace for annealing for 1 to 3 hours at a temperature of 260° C.˜450° C. The titanium metal plate after annealing cools down at a cooling rate of 10° C. per minute so as to obtain a TiO₂ thin film with a crystal structure of anatase phase having photocatalysis effect. The porous TiO₂ thin film can absorb photosensitive dye therein.

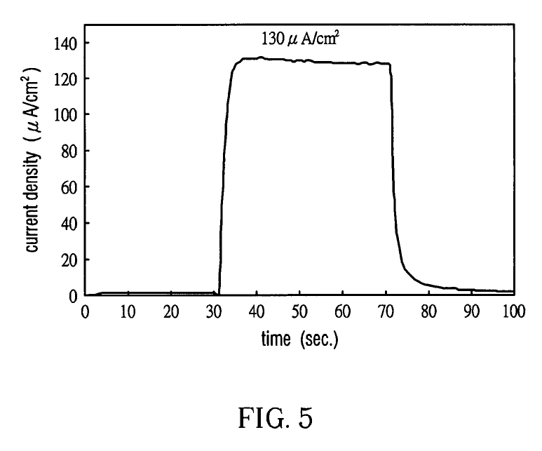

Referring to FIG. 5, under the conditions of excited wavelength of 545 nm and irradiation power at 0.7 mW/cm² per unit area, the dye-sensitized solar cell fabricated according to the aforementioned manufacturing process and conditions, can provide a current density up to 130 μA/cm² and that can be converted into 42.25% IPCE (incident photon-to-current conversion efficiency).

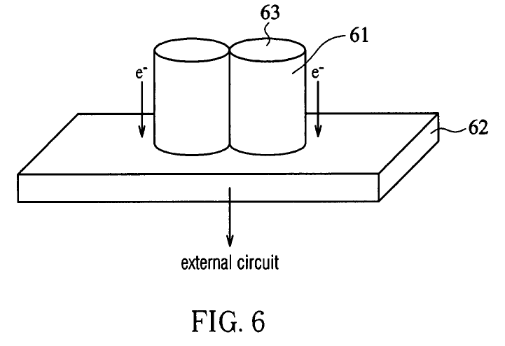

Now refer to FIG. 6, according to the dye-sensitized solar cell of the invention, the TiO₂ thin film is a structure of nanotubes whose diameter is around 100 nm. When a photosensitive dye 63 is absorbed in a nanotube 61, the path for electrons to be transferred to a conductive layer 62 can be shortened. In addition, compared to the conventional manufacturing method that TiO₂ grains are prepared first and then a thin film is formed by coating/deposition, the method in accordance with the invention grows a TiO₂ thin film directly on a metal plate, which provides a simple manufacturing process with relatively short process time and excellent adhesion between the TiO₂ thin film and the metal plate. In addition, the regular arrangement and uniform diameter of the nanotubes contributes to a higher transmission rate for the electrons in the TiO₂ thin film layer. And as shown in FIG. 2, TiO₂ thin films 22 and 22′ can be grown simultaneously on both sides of the metal plate by applying anode treatment. Each TiO₂ thin film, together with photosensitive dyes 23, 23′, transparent substrates 24, 24′ and electrolytic solutions 25 and 25′, can form a dye-sensitized solar cell respectively. Two dye-sensitized solar cells can share one metal plate 21 as the anode thereof. Furthermore, an electrode having a large area can be easily formed by using anode treatment, which is much simpler than conventional methods. Also the metal plate used as an anode can be recycled to be used again efficiently.

The above explanation is by way of illustration and example only and is not to be taken by way of limitation. Various modifications or amendments according to the mentioned embodiments of the invention may be made by persons skilled in the art without departing from the spirit or scope of the invention. Any equivalent modification or amendment without departing from the spirit and scope of the present invention should also be included in the appended claims.

What is claimed is:

1. A dye-sensitized solar cell comprising:
a metal plate made of titanium or titanium alloy, which is used as an anode, a TiO₂ thin film being formed on a surface of the metal plate, the TiO₂ thin film consisting of a plurality of arranged TiO₂ nanotubes;
a photosensitive dye, which is absorbed on the TiO₂ thin film;
a transparent substrate, whose transparent part is a euphotic zone through which light can be irradiated to the photosensitive dye, and a cathode being provided on a surface of the transparent substrate;
an insulating unit, which is located between the anode and the cathode; and
an electrolytic solution, which fills the space between the anode and the cathode and surrounded by the insulating unit.

2. The dye-sensitized solar cell as set forth in claim 1, further comprising a reflection unit to reflect light to the euphotic zone.

3. The dye-sensitized solar cell as set forth in claim 1, wherein the titanium alloy is an alloy of Ti-6A1-4V.

4. The dye-sensitized solar cell as set forth in claim 1, wherein the anode is flexible.

5. The dye-sensitized solar cell as set forth in claim 1, wherein the photosensitive dye is absorbed in the clearances of the TiO₂ nanotubes.

6. The dye-sensitized solar cell as set forth in claim 1, wherein the cathode is made of platinum, graphite or carbon nanotube.

7. The dye-sensitized solar cell as set forth in claim 1, wherein the insulating unit is made of silica gel, plastic, rubber, polymer film or non-conductive ceramics.

8. The dye-sensitized solar cell as set forth in claim 1, wherein two dye-sensitized solar cells share the metal plate as the anode of them.

9. A method for manufacturing a dye-sensitized solar cell, comprising steps of:
forming a TiO₂ thin film on a surface of a metal plate made of titanium or titanium alloy, wherein such TiO₂ thin film consists of a plurality of arranged TiO₂ nanotubes and the metal plate is used as an anode;
performing a thermal operation to change the TiO₂ nanotubes from a crystal structure of amorphous phase into a crystal structure of anatase phase;
absorbing a photosensitive dye onto the surface of the metal plate;
forming a cathode on a surface of a transparent substrate whose transparent part is a euphotic zone through which light can be irradiated to the photosensitive dye; and
filling the space between the anode and the cathode and surrounded by an insulating unit with an electrolytic solution to form the dye-sensitized solar cell.

10. The method for manufacturing a dye-sensitized solar cell as set forth in claim 9, further comprising the step of providing a reflection unit to reflect light to the euphotic zone.

11. The method for manufacturing a dye-sensitized solar cell as set forth in claim 9, wherein the titanium alloy is an alloy of Ti-6Al-4V.

12. The method for manufacturing a dye-sensitized solar cell as set forth in claim 9, wherein the photosensitive dye is absorbed in the clearances of the TiO₂ nanotubes.

13. The method for manufacturing a dye-sensitized solar cell as set forth in claim 9, wherein the cathode is made of platinum, graphite or carbon nanotube.

14. The method for manufacturing a dye-sensitized solar cell as set forth in claim 9, wherein the insulating unit is made of silica gel, plastic, rubber, polymer film or non-conductive ceramics.

15. The method for manufacturing a dye-sensitized solar cell as set forth in claim 9, wherein two dye-sensitized solar cells share the metal plate as the anode of them.

16. The method for manufacturing a dye-sensitized solar cell as set forth in claim 9, wherein the TiO₂ thin film is prepared by performing an anode treatment.

17. The method for manufacturing a dye-sensitized solar cell as set forth in claim 16, wherein the electrolytic solution comprises 0.5˜5% fluoride.

18. The method for manufacturing a dye-sensitized solar cell as set forth in claim 17, wherein the fluoride is hydrofluoric acid (HF), sodium fluoride (NaF), potassium fluoride (KF), ammonium fluoride (NH₄F), or a combination thereof.

19. The method for manufacturing a dye-sensitized solar cell as set forth in claim 17, wherein the electrolytic solution in anode treatment further comprises 5˜30% ((NH₄)H₂PO₄), ((NH₄)SO₄), (H₂C₂O₄) or acid solutions.

20. The method for manufacturing a dye-sensitized solar cell as set forth in claim 19, wherein the acid solution is (H₂SO₄), (H₃PO₄) or (HNO₃).
